(19) United States
(12) Patent Application Publication
(10) Pub. No.: US 2026/0221193 A1
(43) Pub. Date: Jul. 30, 2026

(54) MANAGING PROGRAM OPERATIONS IN MEMORY SYSTEMS

(71) Applicant: Yangtze Memory Technologies Co., Ltd., Wuhan (CN)

(72) Inventors: Wei QI, Wuhan (CN); Da LI, Wuhan (CN); Biao YANG, Wuhan (CN)

(21) Appl. No.: 19/176,131

(22) Filed: Apr. 10, 2025

(30) Foreign Application Priority Data
Jan. 26, 2025 (CN) 202510123736.6

(51) Int. Cl. G11C 16/10; G11C 16/08; G11C 16/30

(52) U.S. Cl. CPC G11C 16/102; G11C 16/08; G11C 16/30

(57) ABSTRACT

Methods, devices, and systems for managing program operations are provided. In one aspect, a memory system includes a memory device, and a memory controller coupled to the memory device. The memory controller is configured to instruct the memory device to write first data in a first single-level cell (SLC) mode using a first program pulse, and in response to detecting that the memory system is disconnected from an external power source, instruct the memory device to write second data in a second SLC mode using a second program pulse. The second program pulse is different from the first program pulse.

### CROSS-REFERENCE TO RELATED APPLICATIONS

This application claims priority to Chinese Patent Application No. 202510123736.6, filed on Jan. 26, 2025, which is hereby incorporated by reference in its entirety.

### TECHNICAL FIELD

The present disclosure generally relates to memory devices and memory systems, and in particular, to managing program operations in memory systems.

### BACKGROUND

Flash memory is a low-cost, high-density, nonvolatile solid-state storage medium that can be electrically erased and reprogrammed. Flash memory includes NOR flash memory and NAND flash memory. Various operations can be performed by flash memory, for example, program (write) and erase operations, to change the threshold voltage of each memory cell to a respective level. For NAND flash memory, an erase operation can be performed at the memory block level, a program operation can be performed at the page level, and a read operation can be performed at the page level.

### SUMMARY

The present disclosure involves methods, apparatuses, and systems for managing program operations in memory systems. One aspect of the present disclosure features an example memory system that includes a memory device, and a memory controller coupled to the memory device. The memory controller is configured to instruct the memory device to write first data in a first single-level cell (SLC) mode using a first program pulse, and in response to detecting that the memory system is disconnected from an external power source, instruct the memory device to write second data in a second SLC mode using a second program pulse. The second program pulse is different from the first program pulse.

In some implementations, the memory device is configured to write the first data in the first SLC mode by applying the first program pulse, and write the second data in the second SLC mode by applying the second program pulse. A voltage of the second program pulse is lower than a voltage of the first program pulse.

In some implementations, the memory device is configured to write the first data in the first SLC mode by applying the first program pulse, and write the second data in the second SLC mode by applying the second program pulse. A duration of the second program pulse is shorter than a duration of the first program pulse.

In some implementations, the memory controller is configured to instruct the memory device to write the second data in the second SLC mode by sending configuration information that indicates the second SLC mode, and sending a write command that instructs the memory device to write the second data.

In some implementations, the memory system includes a power loss protection (PLP) circuit configured to provide power for the memory system when the memory system is disconnected from the external power source.

In some implementations, the PLP circuit comprises a capacitor. The PLP circuit is configured to charge the capacitor when the memory system is connected to the external power source, and discharge the capacitor to provide power for the memory system when the memory system is disconnected from the external power source.

In some implementations, the memory device comprises memory cells programmable in the first SLC mode, the second SLC mode and a third storage mode. Memory cells programmable in the third storage mode have a higher storage density than memory cells programmable in the first SLC mode and the second SLC mode.

In some implementations, the third storage mode includes a triple-level cell (TLC) storage mode or a quad-level cell (QLC) storage mode.

Another aspect of the present disclosure features a method of operating a memory system. The method includes writing first data in a first single-level cell (SLC) mode using a first program pulse, and in response to detecting that the memory system is disconnected from an external power source, writing second data in a second SLC mode using a second program pulse. The second program pulse is different from the first program pulse.

In some implementations, a voltage of the second program pulse is lower than a voltage of the first program pulse.

In some implementations, a duration of the second program pulse is shorter than a duration of the first program pulse.

In some implementations, the method includes sending configuration information that indicates the second SLC mode, and sending a write command that instructs a memory device of the memory system to write the second data.

In some implementations, the method includes discharging a power loss protection circuit to provide power for the memory system when the memory system is disconnected from the external power source.

Another aspect of the present disclosure features a memory device. The memory device comprises a memory array and a peripheral circuit coupled to the memory array. The peripheral circuit is configured to write first data in a first single-level cell (SLC) mode by applying a first program pulse, and in response to receiving configuration information that indicates a second SLC mode, write second data in the second SLC mode by applying a second program pulse. The second program pulse is different from the first program pulse.

In some implementations, a voltage of the second program pulse is lower than a voltage of the first program pulse.

In some implementations, a duration of the second program pulse is shorter than a duration of the first program pulse.

In some implementations, the memory device is configured to receive the configuration information when an external power source of the memory device is disconnected.

In some implementations, the memory device comprises memory cells programmable in the first SLC mode, the second SLC mode and a third storage mode. Memory cells in the third storage mode have a higher storage density than memory cells in the first SLC mode and the second SLC mode.

In some implementations, the third storage mode includes a triple-level cell (TLC) storage mode or a quad-level cell (QLC) storage mode.

In some implementations, the peripheral circuit is configured to apply the second program pulse to a word line to program memory cells coupled to the word line from an erased state to a programmed state.

Another aspect of the present disclosure features a method of operating a memory device The method includes writing first data in a first single-level cell (SLC) mode by applying a first program pulse, and in response to receiving configuration information that indicates a second SLC mode, writing second data in the second SLC mode by applying a second program pulse. The second program pulse is different from the first program pulse.

In some implementations, a voltage of the second program pulse is lower than a voltage of the first program pulse.

In some implementations, a duration of the second program pulse is shorter than a duration of the first program pulse.

While generally described as computer-implemented software embodied on tangible media that processes and transforms the respective data, some or all of the aspects may be computer-implemented methods or further included in respective systems or other devices for performing this described functionality. The details of these and other aspects and implementations of the present disclosure are set forth in the accompanying drawings and the description below. Other features, objects, and advantages of the disclosure will be apparent from the description and drawings, and from the claims.

### BRIEF DESCRIPTION OF DRAWINGS

FIG. 1 illustrates an example of a schematic diagram of a memory device including peripheral circuits, according to some aspects of the present disclosure.

FIG. 2 illustrates an example of a side view of cross-sections of a memory array, according to some aspects of the present disclosure.

FIG. 3 illustrates an example of a schematic diagram of a memory block including strings, according to some aspects of the present disclosure.

FIG. 4 illustrates an example of a plan view of cross-sections of a memory block including strings, according to some aspects of the present disclosure.

FIG. 5 illustrates some example peripheral circuits, according to some aspects of the present disclosure.

FIG. 6 illustrates a block diagram of a memory system including a power loss protection (PLP) circuit, according to some aspects of the present disclosure.

FIG. 7A illustrates example threshold voltage distributions corresponding to a two-step program operation, according to some aspects of the present disclosure.

FIGS. 7B-7C illustrate example sequences of coarse programming and fine programming when programming a memory block, according to some aspects of the present disclosure.

FIGS. 8A-8B illustrate example program pulses implemented by a normal single-level cell (SLC) mode and by a power-loss SLC mode, according to some aspects of the present disclosure.

FIG. 9 illustrates example performances of a normal SLC mode and a power-loss PLC mode, according to some aspects of the present disclosure.

FIG. 10 illustrates an example process of performing program operations, according to some aspects of the present disclosure.

FIG. 11 illustrates a flow chart of an example process of operating a memory system, according to some aspects of the present disclosure.

FIG. 12 illustrates a memory block diagram of an example system having a memory device, according to some aspects of the present disclosure.

FIG. 13A illustrates a diagram of a memory card having a memory device, according to some aspects of the present disclosure.

FIG. 13B illustrates a diagram of a solid-state drive (SSD) having a memory device, according to some aspects of the present disclosure.

Like reference numbers and designations in the various drawings indicate like elements.

### DETAILED DESCRIPTION

This specification relates to memory devices, memory systems, and methods for managing program operations. A memory system (e.g., an enterprise solid-state drive) can include a memory controller and a memory device comprising memory cells programmable in a single-level cell (SLC) mode, and in a storage mode with a higher storage density (e.g., a triple-level cell (TLC) mode, a quad-level cell (QLC) mode, or a penta-level cell (PLC) mode). For example, the memory system can write system data to the memory device in the SLC mode, and write user data to the memory device in the storage mode with higher storage density.

The memory system can have a power-loss protection (PLP) circuit configured to provide power for the memory system in the event of sudden power loss. The PLP circuit can include a capacitor that stores electrical energy, which can be released to power the memory system in the event of sudden power loss, so that unfinished operations (e.g., unfinished program operations) can be completed. In some cases, data associated with unfinished program operations can be written to the memory device in the SLC mode.

As the storage capacity of memory systems increases, there can be a larger amount of data associated with unfinished program operations, which needs to be written to the memory device in the event of sudden power loss. Given the difficulty of increasing the size of the capacitor of the PLP circuit (which may increase the die size of the memory system), data needs to be written more efficiently in the event of sudden power loss.

The present disclosure provides techniques to write data in a more efficient and energy-saving way in the event of sudden power loss. In some implementations, when the memory system is properly powered, the memory controller can instruct the memory device to write data (e.g., system data) in a normal SLC mode, e.g., by applying a first program pulse to selected word lines. In addition, the memory device can write data (e.g., user data) in a storage mode with a higher storage capacity. In the event of sudden power loss, the memory controller can instruct the memory device to write data (e.g., data associated with unfinished program operations) in a power-loss SLC mode, e.g., by applying a second program pulse to selected word lines. The second program pulse can have a lower voltage and/or a shorter duration than the first program pulse.

The described techniques can achieve one or more technical effects. For example, by writing data in the power-loss SLC mode, less power is consumed compared to writing data in the normal SLC mode. As such, a smaller capacitor can be used to power the memory system to complete unfinished program operations, which can reduce the cost of the memory system. For another example, the described techniques do not require changing hardware circuitries of the memory system and can improve the reliability of the memory device in a cost-efficient way. In some implementations, additional or different technical effects can be achieved.

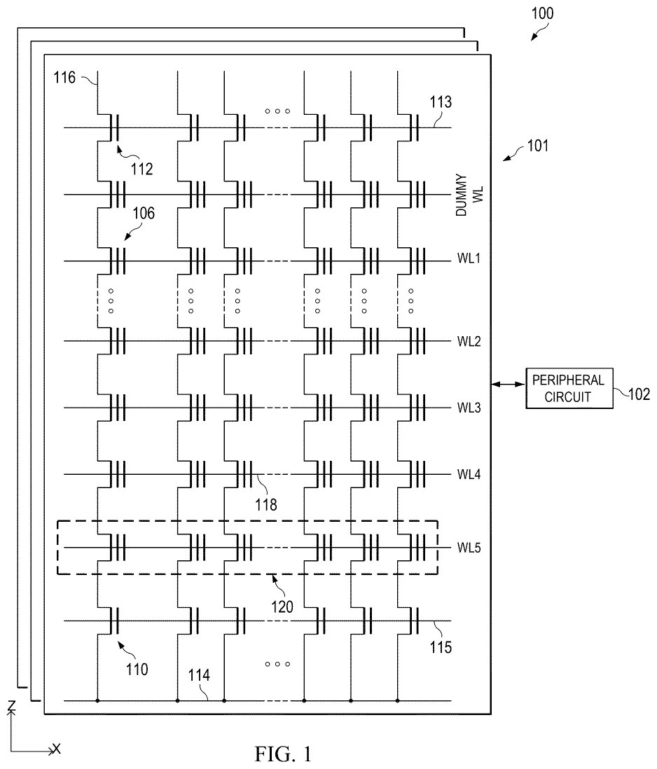

FIG. 1 illustrates an example of a schematic circuit diagram of a memory device 100 including peripheral circuits, according to some aspects of the present disclosure. The memory device 100 can include a memory array 101 and peripheral circuits 102 coupled to the memory array 101. The memory array 101 can be a NAND flash memory array that includes NAND memory cells 106 arranged in rows and columns. In some implementations, memory cells 106 in a column (e.g., along z direction) of the memory array 101 are coupled in series and stacked vertically. Memory cells 106 in a row (e.g., along x direction) of the memory array 101 are coupled to and controlled by a word line 118. Each memory cell 106 can hold a continuous, analog value, such as an electrical voltage or charge that depends on the number of electrons trapped within a storage layer of the memory cell 106. The logic state (i.e., data) of each memory cell 106 can be determined based on the threshold voltage Vₜₕ of the memory cell 106. Each memory cell 106 can be a floating gate type memory cell including a floating-gate transistor, or a charge trap type memory cell including a charge-trap transistor.

In some implementations, a memory cell 106 is configured to be programmable in a single-level cell (SLC) mode, where the memory cell 106 has two possible memory states and can store one bit of data. For example, the first memory state “0” (e.g., erased state) can correspond to a first range of voltages, and the second memory state “1” (e.g., programmed state) can correspond to a second range of voltages. In some implementations, to increase storage capacity, a memory cell 106 can be configured to be programmable in a multi-level cell (MLC) mode, a triple-level cell (TLC) mode, a quad-level cell (QLC), or a penta-level cell (PLC) mode. In the MLC mode, a memory cell stores 2 bits of data, and has four logic states, logic {11, 10, 01, and 00}, i.e., erased state L0, and programmed states L1, L2, and L3. In the TLC mode, a memory cell stores 3 bits of data, and has eight logic states, logic {111, 110, 101, 100, 011, 010, 001, 000}, i.e., erased state L0, and programmed states L1-L7. In the QLC mode, a memory cell stores 4 bits of data and has 16 logic states, logic {1111, 1110, 1101, 1100, 1011, 1010, 1001, 1000, 0111, 0110, 0101, 0100, 0011, 0010, 0001, 0000}, i.e., erased state L0 and programmed states L1-L15. In the PLC mode, a memory cell stores 5 bits of data and has 32 logic states, i.e., erased state L0 and programmed states L1-L31.

As shown in FIG. 1, memory cells 106 in a column of the memory array 101 can be coupled to a source select gate (SSG) transistor 110 at its source end, and a drain select gate (DSG) transistor 112 at its drain end. The SSG transistor 110 and the DSG transistor 112 can be configured to activate selected columns of the memory array 101 during read and program operations. In some implementations, sources of the SSG transistors in the same memory block are coupled through a same source line 114. The drain of each DSG transistor is coupled to a respective bit line 116. From the bit line 116, data can be read from, or written to memory cells in the column of memory array 101. In some implementations, each column of the memory array 101 is configured to be selected or deselected by applying a DSG select voltage or a DSG unselect voltage to the gate of the respective DSG transistor 112 through one or more DSG lines 113, and/or by applying a select voltage or a unselect voltage to the gate of the respective SSG transistor 110 through one or more SSG lines 115.

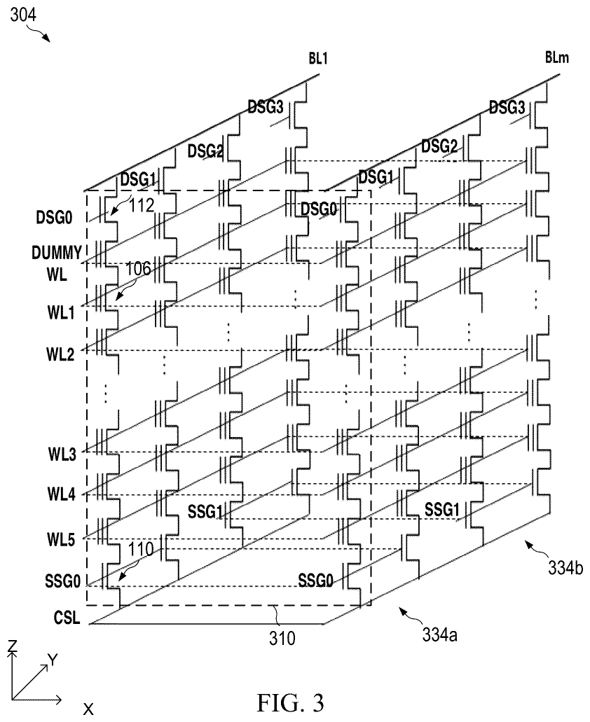

In some implementations, memory cells of adjacent columns can be coupled through word lines 118. Memory cells in a row can form a memory page 120 (e.g., a physical page). The word line 118 can select which memory page 120 is affected by read and program operations. Each word line 118 can include a gate line coupled to a plurality of control gates (gate electrodes) of one or more memory pages 120. For example, if the memory block includes N strings (e.g., strings 310 of FIG. 3), each word line can include a gate line coupled to control gates of N memory pages 120 that are at the same vertical position in respective strings. Example word lines shown in FIG. 1 include WL1, WL2, WL3, WL4, and WL5 that are between DSG line 113 and SSG line 115. In some implementations, the word lines can further include dummy word lines coupled to dummy memory cells.

Peripheral circuits 102 can be coupled to memory array 101 through bit lines 116, word lines 118, source lines 114, SSG lines 115, and DSG lines 113. Peripheral circuits 102 can include any suitable analog, digital, and mixed-signal circuits for facilitating the operations of memory array 101 by applying and sensing voltage signals and/or current signals to and from each target memory cell 106 through bit lines 116, word lines 118, source lines 114, SSG lines 115, and DSG lines 113. Peripheral circuits 102 can include various types of peripheral circuits formed using metal-oxide-semiconductor (MOS) technologies.

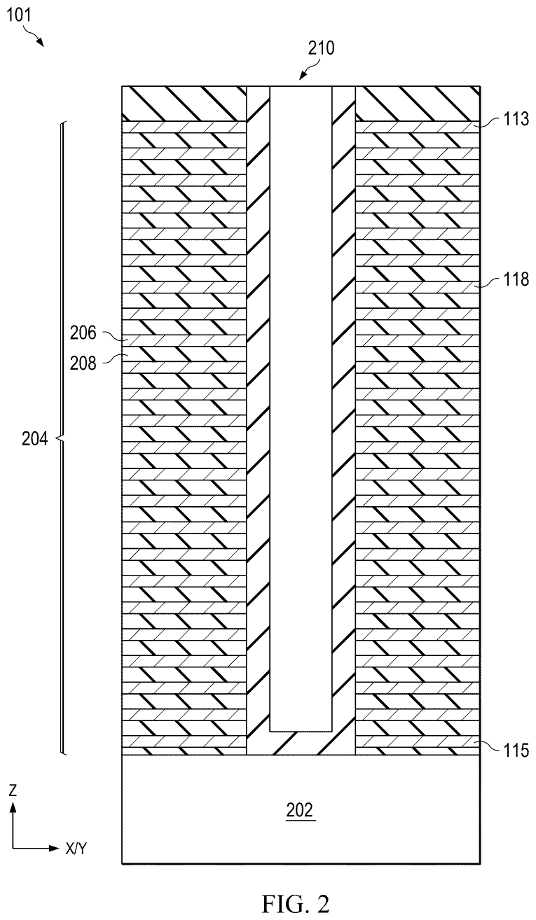

FIG. 2 illustrates an example of a side view of cross-sections of a memory array 101, according to some aspects of the present disclosure. As shown in FIG. 2, memory cells 106 in a column of memory array 101 can be coupled in series and extend vertically through a memory stack 204 above a substrate 202. The substrate 202 can include silicon (e.g., single crystalline silicon), silicon germanium (SiGe), gallium arsenide (GaAs), germanium (Ge), silicon on insulator (SOI), germanium on insulator (GOI), or any other suitable materials.

The memory stack 204 can include pairs of interleaved gate conductive layers 206 and gate-to-gate dielectric layers 208. The quantity of the pairs of the interleaved gate conductive layers 206 and gate-to-gate dielectric layers 208 in a memory stack 204 can determine the quantity of memory cells 106 in the memory array 101. The gate conductive layer 206 can include conductive materials including, but not limited to, one or more of tungsten (W), cobalt (Co), copper (Cu), aluminum (Al), polysilicon, doped silicon, or silicide. In some implementations, each gate conductive layer 206 includes a metal layer, such as a tungsten layer. In some implementations, each gate conductive layer 206 includes a doped polysilicon layer. Each gate conductive layer 206 can include control gates surrounding the memory cells 106, the DSG transistor 112, or the SSG transistor 110, and can extend laterally as the DSG line 113 at the top of memory stack 204, the SSG line 115 at the bottom of memory stack 204, or the word lines 118 between the DSG line 113 and the SSG line 115. The memory stack 204 can include one or more channel structures 210 that extend vertically through the pairs of interleaved gate conductive layers 206 and gate-to-gate dielectric layers 208. The channel structure 210 can include semiconductor materials including, but not limited to polysilicon. In some implementations, the channel structure 210 can have a cylinder shape, such that a cross section of the channel structure 210 in the xy plane can have a circle shape.

FIG. 3 illustrates an example of a schematic diagram of a memory block 304 including strings 310, according to some aspects of the present disclosure. In some implementations, the memory array 101 can include a plurality of memory blocks 304. Each memory block 304 can serve as a basic data unit for erase operations, such that memory cells 106 in the same memory block 304 are erased at the same time. To erase memory cells 106 in a selected memory block 304, the source lines (e.g., source line 114 of FIG. 1) coupled to the selected memory block 3034 and unselected memory blocks in the same plane can be biased with an erase voltage. For example, the erase voltage can be a high positive voltage (e.g., 20 V or more). In some implementations, an erase operation can be performed at a half-memory block level, a quarter-memory block level, or a level having any suitable number of memory blocks or fractions of a memory block.

In some implementations, a memory array (e.g., memory array 101 of FIG. 1) can include one or more memory blocks 304 having memory cells 106 programmable in the SLC mode, and one or more memory blocks 304 having memory cells 106 programmable in an XLC mode (e.g., MLC, TLC, QLC or PLC mode) and therefore having a higher storage density.

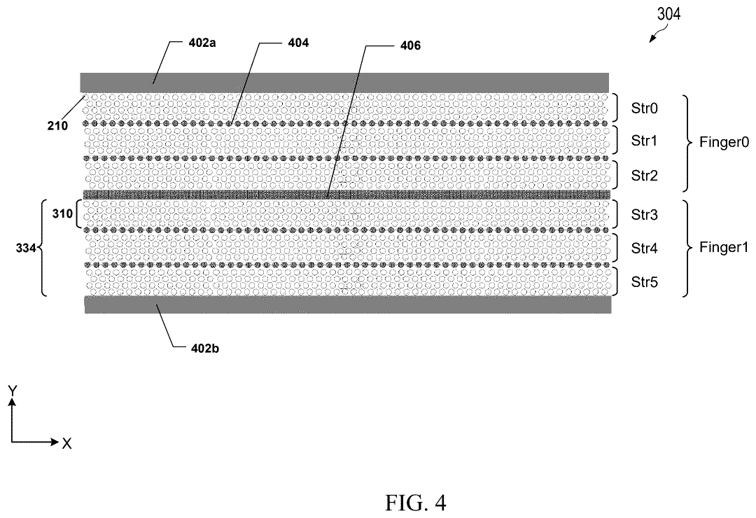

In some implementations, the memory block 304 can include a plurality of strings 310. Each string 310 can include memory cells 106 arranged in rows (e.g., coupled to word lines along x direction) and in columns (e.g., connected in series along z direction). DSG transistors 112 of the same string 310 are coupled to the same DSG line (e.g., DSG line 113 of FIG. 1). DSG lines of different strings 310 are separate from each other by DSG cuts (e.g., DSG cut 404 of FIG. 4), so that each string 310 in the memory block 304 can be selected or deselected by applying a select voltage or an unselect voltage to the respective DSG line. For example, DSG transistors 112 of a first string in the memory block 304 are coupled to a first DSG line represented by DSG0; DSG transistors 112 of a second string in the memory block 304 are coupled to a second DSG line represented by DSG1; DSG transistors 112 of a third string in the memory block 304 are coupled to a third DSG line represented by DSG2; and DSG transistors 112 of a fourth string in the memory block 304 are coupled to a fourth DSG line represented by DSG3.

In some implementations, memory cells 106 in adjacent strings 310 can be coupled through word lines. Example word lines shown in FIG. 4 include Dummy WL, WL1, WL2, WL3, WL4, and WL5. For example, memory cells 106 of the same vertical position (e.g., along z direction) in adjacent strings 310 are coupled to the same word line.

In some implementations, memory block 304 can be divided into fingers 334a, 334b (collectively as 334). Each finger 334 can include one or more strings 310. SSG transistors 110 of strings 310 in the same finger 334 are coupled to the same SSG line (e.g., SSG line 115 of FIG. 1), so that each finger 334 can be selected or deselected by applying a select voltage or an unselect voltage to the respective SSG line 115. SSG lines of different fingers 334 are separate from each other by SSG cuts (e.g. SSG cut 406 of FIG. 4). For example, SSG transistors 110 of strings 310 in the first finger 334a are coupled to a first SSG line represented by SSG0; SSG transistors 110 of strings 310 of the second finger 334b are coupled to a second SSG line represented by SSG1.

In some implementations, the memory block 304 can include a different number of fingers 334, and each finger 334 can include a different number of strings 310. In some implementations, the strings 310 are not arranged into fingers 334, for example, by coupling SSG transistors of all strings 310 of the memory block 304 to the same SSG line. As such, by applying select or unselect voltage to the SSG line in the memory block 304, the entire memory block 304 can be selected or deselected.

FIG. 4 illustrates an example of a plan view of cross-sections of a memory block 304 including strings 310, according to some aspects of the present disclosure. In some implementations, the memory block 304 is separated from adjacent memory blocks (not shown in FIG. 4) by gate line slit structures 402a, 402b. For example, the gate line slit structure 402a can be a first boundary of the memory block 304, and the gate line slit structure 402b can be a second boundary of the memory block 304.

In some implementations, the memory block 304 can include a plurality of strings 310. Each string 310 can include a plurality of channel structures 210 that extend vertically to connect a series of memory cells. The channel structures 210 are arranged in rows along x direction. In some implementations, each string 310 can include more than one row of channel structures 210.

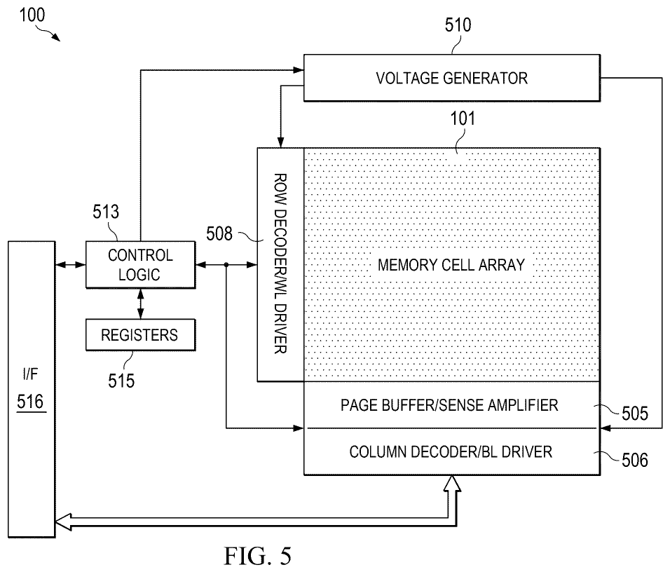

The strings 310 are separated from each other by DSG cuts 404, which can electrically separate DSG lines 113 of different strings 310. As such, each string 310 can be individually selected or deselected by applying DSG voltages to respective DSG line 113. In some implementations, each DSG cut 404 is arranged between two rows of channel structures 210, as shown in FIG. 4. In some other implementations, each DSG cut 404 is arranged on a row of channel structures 210, as shown in FIG. 5.

In some implementations, the strings 310 can be arranged into fingers 334. The fingers are separated from each other by SSG cuts 406, which can electrically separate SSG lines 115 of different fingers 334. As such, each finger 334 can be individually selected or deselected by applying SSG voltage to respective SSG lines 115.

As an example shown in FIG. 4, the memory block 304 includes two fingers 334 separated by SSG cuts 406, and each finger 334 includes three strings 310 separated by DSG cuts 404. For instance, a first finger (Finger1) includes String1-3, a second finger (Finger2) includes String4-6, and a third finger (Finger3) includes String7-9. In some implementations, the memory block 304 can include a different number of fingers 334, and each finger 334 can include a different number of strings 310.

In some implementations, the memory block 304 is not divided into fingers 334, such that SSG lines 115 of all strings 310 in the same memory block 304 are electrically connected, without having SSG cuts 406.

FIG. 5 illustrates some example peripheral circuits, according to some aspects of the present disclosure. The example peripheral circuits include a page buffer/sense amplifier 505, a column decoder/bit line driver 506, a row decoder/word line driver 508, a voltage generator 510, control logic 513, registers 515, an interface 516, and a data bus. In some examples, additional peripheral circuits not shown in FIG. 5 may be included as well.

The page buffer/sense amplifier 505 can be configured to read and program (write) data from and to memory array 101 according to the control signals from control logic 513. In an example, the page buffer/sense amplifier 505 may store one page of program data (write data) to be programmed into one page of the memory array 101. In another example, the page buffer/sense amplifier 505 may perform program verification operations to ensure that the data has been properly programmed into memory cells 106 coupled to selected word lines 118. In still another example, the page buffer/sense amplifier 505 may also sense the low power signals from the bit line 116 that represents a data bit stored in memory cell 106, and amplify the small voltage swing to recognizable logic levels in a read operation. The column decoder/bit line driver 506 can be configured to be controlled by the control logic 513 and select one or more strings 310 by applying bit line voltages generated from the voltage generator 510.

The row decoder/word line driver 508 can be configured to be controlled by the control logic 513 and select/unselect memory blocks 304 of the memory array 101 and select/unselect word lines 118 of the memory block 304. The row decoder/word line driver 508 can be further configured to drive word lines 118 using word line voltages generated from the voltage generator 510. In some implementations, the row decoder/word line driver 508 can also select/unselect and drive SSG lines 115 and DSG lines 113. As described below in detail, the row decoder/word line driver 508 is configured to apply a program voltage to selected word line 118 in a program operation on memory cell 106 coupled to selected word line 118.

The voltage generator 510 can be configured to be controlled by the control logic 513 and generate the word line voltages (e.g., read voltage, program voltage, pass voltage, local voltage, verify voltage, etc.), bit line voltages, and source line voltages to be supplied to the memory array 101.

The control logic 513 can be coupled to each peripheral circuit described above and configured to control operations of each peripheral circuit. The registers 515 can be coupled to the control logic 513 and include status registers, command registers, and address registers for storing status information, command operation codes (OP codes), and command addresses for controlling the operations of each peripheral circuit.

The interface 516 can be coupled to the control logic 513 and act as a control buffer to buffer and relay control commands received from a host (not shown) to the control logic 513 and status information received from the control logic 513 to the host. The interface 516 can also be coupled to the column decoder/bit line driver 506 via a data bus, and act as a data input/output (I/O) interface and a data buffer to buffer and relay data to and from the memory array 101.

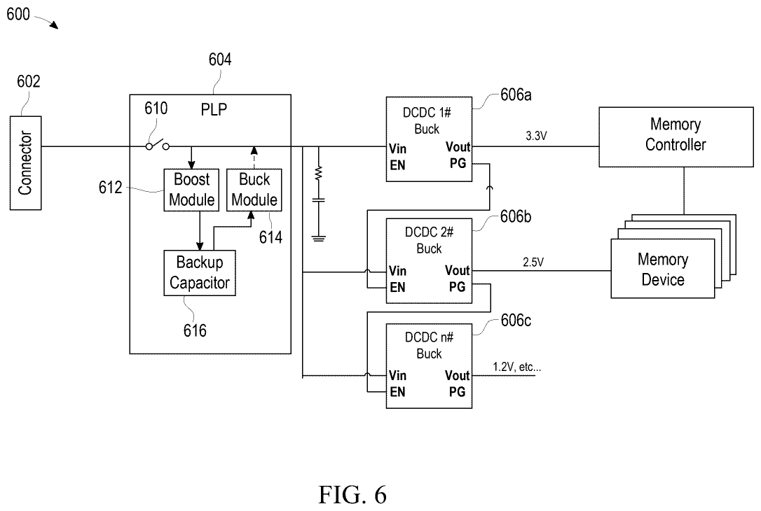

FIG. 6 illustrates a block diagram of a memory system 600 including a power loss protection (PLP) circuit 604, according to some aspects of the present disclosure. The memory system 600 can include a connector 602, a power loss protection (PLP) circuit 604, one or more voltage converters 606a, 606b, 606c (collectively 606), a discharge circuit 608, a memory controller, and a memory device.

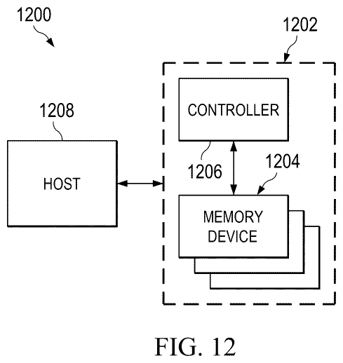

The connector 602 is configured to connect the memory system 600 to an external power source, for example, to a motherboard of a host (e.g., host 1208 of FIG. 12). The connector 602 can include a set of pins used for data transmission, and a set of pins used for power supply. For example, the connector 602 can deliver a power of 5V to the memory system 600.

The PLP circuit 604 can be configured to provide power for the memory system 600 in case of a power loss (e.g., when the memory system 600 is disconnected from the external power source). The PLP circuit 604 can include a load switch 610, a boost module 612, a buck module 614, and a backup capacitor 616. The PLP circuit 604 is coupled to the connector 602. When power is delivered to the PLP circuit 604 from the connector 602, the load switch 610 is turned on, so that the PLP circuit 604 can deliver power to the voltage converters 606 (including 606a, 606b, and 606c). In addition, the boost module 612 can elevate the voltage of the power from the connector 602 to a higher voltage, for example, from 5V to 30V, and charge the backup capacitor 616 using the higher voltage. When the memory system 600 is disconnected from the external power source, no power is delivered to the PLP circuit 604 from the connector 602. In such case, the load switch 610 is turned off, so that the backup capacitor 616 can discharge its electrical energy to provide power for the memory system 600, which allows the memory system 600 to complete unfinished operations (e.g., unfinished program operations) to maintain data integrity. In some implementations, the buck module 614 is configured to lower the voltage of the power discharged by the backup capacitor 616 to a voltage suitable to power the memory system 600, for example, from 30V to 3-5V. Once the connection to the external power source is restored, for example, when the memory system 600 is reconnected to the host, the backup capacitor 616 can be recharged to be ready for a future power loss.

A voltage converter 606 (e.g., a DC-DC converter) can be configured to convert an input voltage (e.g., the output voltage of the PLP circuit 604) to an output voltage suited to power a specific component of the memory system 600. The memory system 600 can include a set of voltage converters 606 connected in series. Each voltage converter 606 can include an input (Vin) pin connected to the output of the PLP circuit 604, an enable (EN) pin configured to activate or deactivate the voltage converter 606, an output (Vout) pin connected to a voltage line that powers a specific component of the memory system 600, and a status pin (e.g., power good (PG) pin) that indicates whether the output power of the voltage converter is good. In some implementations, except for the first voltage converter 606a, the enable pin of a voltage converter 606 is connected to the status pin of the preceding voltage converter 606. For example, when the power of first voltage converter 606a is good, its status pin can output a high voltage. The enable pin of the second voltage converter 606b can receive the high voltage, which indicates to activate the second voltage converter 606b. When the power of the second voltage converter 606b is good, its status pin can output a high voltage. The enable pin of the third voltage converter 606c can receive the high voltage, which indicates to activate the third voltage converter 606c, and so on. As such, the voltage converters 606 connected in series can be activated sequentially.

In some implementations, as shown in FIG. 6, the first voltage converter 606a is configured to convert the output voltage of the PLP circuit 604 to a first voltage (e.g., 3.3 V) suited to power the memory controller. The output pin of the first voltage converter 606a can be connected to a voltage line that provides power for the memory controller. The second voltage converter 606b is configured to convert the output voltage of the PLP circuit 604 to a second voltage (e.g., 2.5 V) suited to power the memory device. The output pin of the second voltage converter 606b can be connected to a voltage line that provides power for the memory device. The third voltage converter 606c is configured to convert the output voltage of the PLP circuit 604 to another voltage (e.g., 1.2V) suited to power another component of the memory system 600. In some implementations, the memory system can include a different number of voltage converters 606.

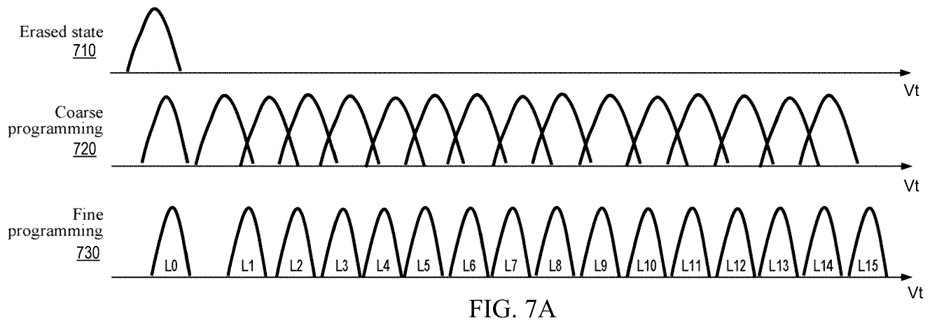

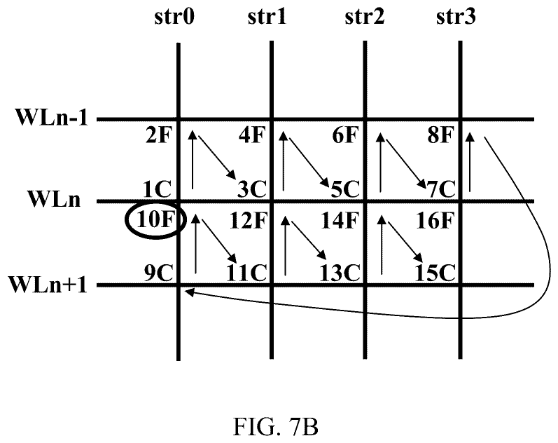

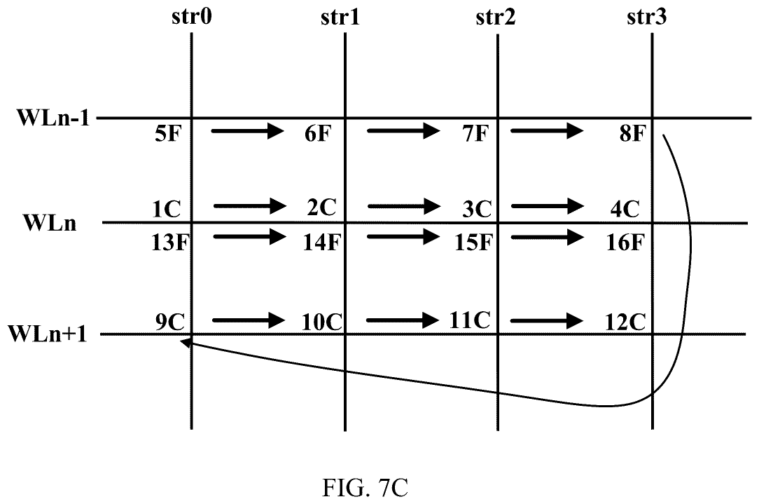

FIG. 7A illustrates example threshold voltage distributions corresponding to a two-step program operation, according to some aspects of the present disclosure.

To write data in an XLC mode (e.g., a TLC mode, a QLC mode, or a PLC mode), the memory device can perform a two-step program operation that includes coarse programming 720 and fine programming 730. QLC mode is used as an example below for illustration.

As shown in FIG. 7A, before the two-step program operation, memory cells in a target memory page (e.g., memory page 120 of FIG. 1) are in an erased state 710.

During coarse programming 720, the memory cells in the target memory page can be programmed to a set of intermediate levels, for example, by applying a set of program voltages (e.g., an incremental step pulse programming (ISPP) scheme) to a word line (e.g., word line 118 of FIG. 1) coupled to the target memory page. As an example, as shown in FIG. 7A, the set of intermediate levels includes 16 levels. Threshold distributions of adjacent intermediate levels may partially overlap with one another. In some implementations, the set of intermediate levels can include 2 levels, 4 levels, or 8 levels, as suited.

After coarse programming 720, fine programming 730 is performed on the target memory page. During fine programming 730, the memory cells in the target memory page can be programmed to 16 final levels including the erased state L0 and the programmed states L1-L15, for example, by applying a set of program voltages (e.g., an ISPP scheme) to the word line coupled to the target memory page. The threshold distribution of each final level can have a smaller voltage range than an intermediate level.

Data to be programmed into the target memory page can be retained in a data buffer of a memory controller (e.g., the memory controller 1206 of FIG. 12) until the fine programming 730 is completed. In the event of a power loss, the memory system needs to complete unfinished program operations using the power provided by the PLP circuit (e.g., PLP circuit 604 of FIG. 6). Unfinished program operations can include two-step program operations where, at the moment of power loss, coarse programming 720 is completed but fine programming 730 is not yet completed. In some implementations, the memory system can complete unfinished program operations by writing data associated with the unfinished program operations to the memory device in an SLC mode. For example, a single program pulse can be applied to a word line to program memory cells from an erased state to a single programmed state. As such, less power is needed to complete unfinished program operations, compared to writing data associated with the unfinished program operations in the XLC mode.

FIGS. 7B-7C illustrate example sequences of coarse programming and fine programming when programming a memory block (e.g., a memory block 304 of FIGS. 1, 3 and 4), according to some aspects of the present disclosure. The memory block can include a number of strings (e.g., string 310 of FIG. 3), for example, Str0 to Str3. Each string can include a number of memory pages (represented by intersection points in FIGS. 7B-7C), which are each coupled to a respective word line of a set of word lines numbered in sequence. For illustration purposes, in FIGS. 7B-7C, memory pages coupled to WLn−1 have undergone coarse programming.

In some implementations, fine programming on memory pages coupled to a preceding word line (e.g., WLn−1) is performed alternatively with coarse programming on memory pages coupled to a following word line (e.g., WLn). For example, as shown in FIG. 7B, programming the memory block follows the sequence of: coarse programming on the memory page coupled to WLn in Str0, fine programming on the memory page coupled to WLn−1 in Str0, coarse programming on the memory page coupled to WLn in Str1, fine programming on the memory page coupled to WLn−1 in Str0, coarse programming on the memory page coupled to WLn in Str2, fine programming on the memory page coupled to WLn−1 in Str2, coarse programming on the memory page coupled to WLn in Str3, fine programming on the memory page coupled to WLn−1 in Str3, and then coarse programming on the memory page coupled to WLn+1 in Str0. Coarse programming on memory pages coupled to WLn+1 and fine programming on memory pages coupled to WLn can be performed following a similar sequence.

In the example shown in FIG. 7B, if a power loss occurs during fine programming of the memory page coupled to WLn in Str0 (10F in FIG. 7B), unfinished program operations include, at least, program operations on all memory pages coupled to WLn, and the memory page coupled WLn+1 in Str0.

In some implementations, fine programming on memory pages coupled to a preceding word line (e.g., WLn−1) is performed following coarse programming on memory pages coupled to a following word line (e.g., WLn). For example, as shown in FIG. 7C, programming the memory block follows the sequence of: coarse programming on memory pages coupled to WLn (e.g., from Str0 to Str3), fine programming on memory pages coupled to WLn−1, coarse programming on memory pages coupled to WLn+1, and then fine programming on memory pages coupled to WLn.

In the example shown in FIG. 7C, if a power loss occurs during coarse programming of the memory page coupled to WLn+1 in Str1 (10C in FIG. 7C), unfinished program operations include, at least, program operations on all memory pages coupled to WLn, the memory page coupled WLn+1 in Str0, and the memory page coupled to WLn+1 in Str1.

It should be noted that the sequence of coarse programming and fine programming in FIGS. 7B-7C are examples only. In some implementations, the memory system can follow other suited sequences of coarse programming and fine programming when programming a memory block.

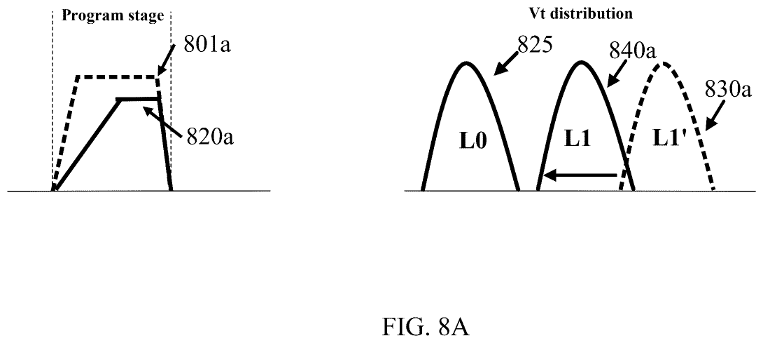

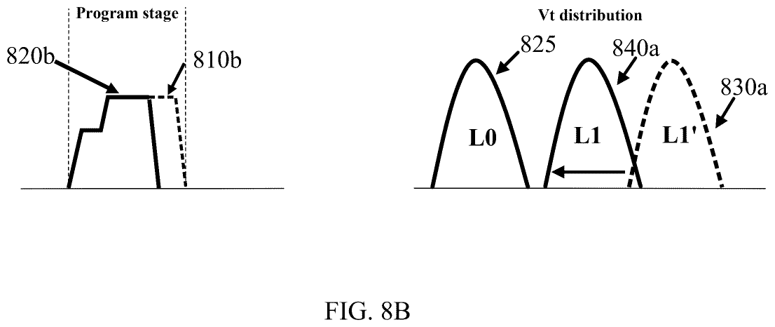

FIGS. 8A-8B illustrate example program pulses implemented by a normal single-level cell (SLC) mode and by a power-loss SLC mode, according to some aspects of the present disclosure. In some implementations, a memory device can be configured to write data in more than one SLC mode, for example, a normal SLC mode and a power-loss SLC mode.

In the normal SLC mode, a first program pulse 810 (including 810a and 810b) can be applied to a selected word line to program memory cells from an erased state 825 to a programmed state 830 (including 830a and 830b). In some implementations, while user data are written to the memory device in an XLC mode (e.g., a TLC mode, a QLC mode, or a PLC mode), host data (for example, mapping tables) can be written to the memory device in the normal SLC mode, for example, to a memory block comprising memory cells programmable in a SLC mode.

In the power-loss SLC mode, a second program pulse 820 (including 820a and 820b) can be applied to a selected word line to program memory cells from an erased state 825 to a programmed state 840 (including 840a and 840b). In some implementations, in response to detecting the memory system is disconnected from the external power source, the memory system can use the power provided by the PLP circuit (e.g., the PLP circuit 604 of FIG. 6) to write data (e.g., data associated with unfinished program operations) in the power-loss SLC mode. The second program pulse 820 is different from the first program pulse 810. In some implementations, as shown in FIG. 8A, the second program pulse 820a has a lower voltage than the first program pulse 810 a. For example, the voltage of the first program pulse 810 a ranges from 17-19V, and the voltage of the second program pulse 820 a can be 60%-80% of the voltage of the first program pulse 810a. In some implementations, as shown in FIG. 8B, the second program pulse 820b has a shorter duration than the first program pulse 810b. For example, the duration of the first program pulse 810 b ranges from 15-20 μs, and the duration of the second program pulse 820 b can be 60%-80% of the duration of the first program pulse 810b.

As such, threshold voltage (Vt) distribution corresponding to the programmed state 840 under the power-loss SLC mode may be closer to the Vt distribution of the erased state 825, compared to the Vt distribution of the programmed state 830 under the normal SLC mode.

In some implementations, the memory controller can send configuration information (e.g., a set feature) to the memory device to indicate the power-loss SLC mode. As such, in response to receiving the configuration information, the memory device can switch from normal SLC mode to power-loss SLC, and write subsequent data in the power-loss SLC mode.

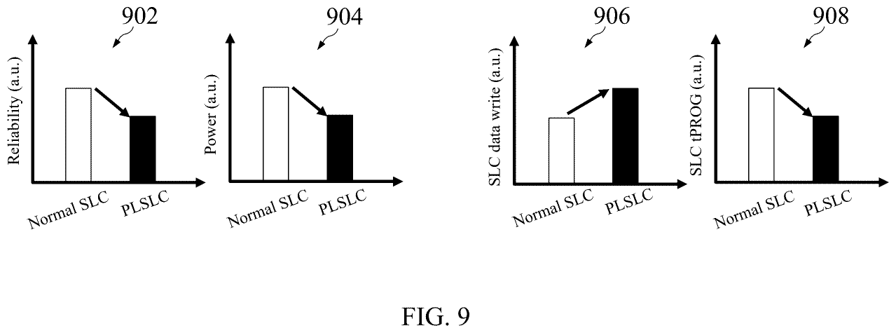

FIG. 9 illustrates example performances of a normal SLC mode (e.g., using the first program pulse 810 of FIGS. 8A-8B) and a power-loss SLC mode (e.g., using the second program pulse 820 of FIGS. 8A-8B), according to some aspects of the present disclosure.

Although data reliability under the power-loss SLC mode may not be as good as data reliability under the normal SLC mode (as shown by diagram 902), under the power-loss SLC mode, less power is needed to write the same amount of data (as shown by diagram 904), more data can be programmed using the power provided by the PLP circuit in the event of a power loss (as shown by diagram 906), and the time needed to perform a program operation can be reduced (as shown by diagram 908).

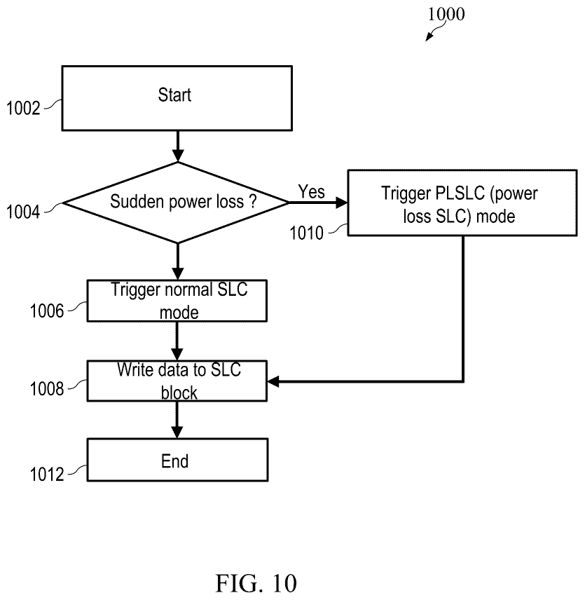

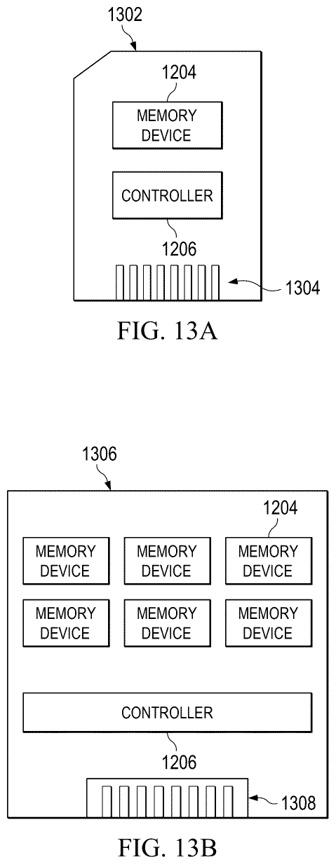

FIG. 10 illustrates an example process 1000 of performing program operations, according to some aspects of the present disclosure. Process 1000 can be performed by any suitable device or system as described herein, for example, according to the example techniques described with respect to FIGS. 1-19. For example, process 1000 can be performed by a memory controller, such as the memory controller 1206 of FIGS. 12-13B, that is coupled to a memory device (e.g., the memory device 100 of FIG. 1, or the memory device 1204 of FIGS. 12-13B).

The operations shown in process 1000 may not be exhaustive and that other operations can be performed as well before, after, or in between any of the illustrated operations. Further, some of the operations may be performed simultaneously, or in a different order than shown in FIG. 10. In some implementations, some of the operations may be performed by or one or more components of a device or a system, such as, a peripheral circuit of the memory device.

The process 1000 starts at 1002.

At 1004, in response to detecting a sudden power loss (e.g., the memory system is suddenly disconnected from the external power source), the process 1000 proceeds to 1010. If the memory system stays connected to the external power source, the process 1000 proceeds to 1006, where the memory system is configured to write certain data (e.g., system data) in a normal SLC mode, e.g., by applying the first program pulse 810 to selected word lines. In the meantime, the memory system can use an XLC mode (e.g., TLC mode, QLC mode, or PLC mode) to program other data (e.g., user data).

At 1010, the memory system can be configured to program data (e.g., data associated with unfinished program operations) in a power-loss SLC mode, e.g., by applying the second program pulse 820 to selected word lines.

At 1008, the memory device can write data to a memory block comprising memory cells in the SLC mode.

The process ends at 1012.

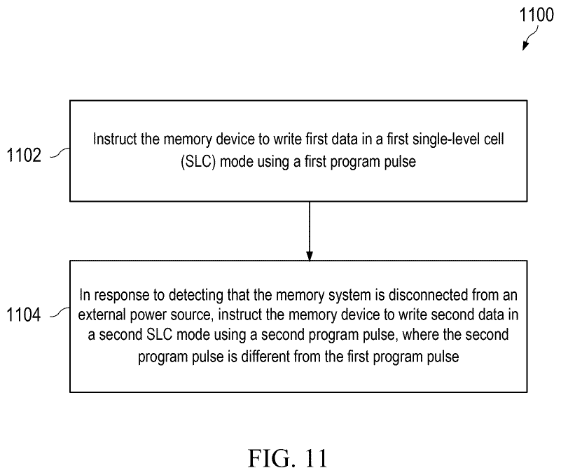

FIG. 11 illustrates a flow chart of an example process 1100 for operating a memory system (e.g., memory system 600 of FIG. 6, memory system 1202 of FIG. 12), according to some aspects of the present disclosure. Process 1100 can be performed by any suitable device or system as described herein, for example, according to the example techniques described with respect to FIGS. 1-10. For example, process 1100 can be performed by a memory controller, such as the memory controller 1206 of FIGS. 12-13B, that is coupled to a memory device (e.g., the memory device 100 of FIG. 1, or the memory device 1204 of FIGS. 12-13B).

The operations shown in process 1100 may not be exhaustive and that other operations can be performed as well before, after, or in between any of the illustrated operations. Further, some of the operations may be performed simultaneously, or in a different order than shown in FIG. 11. In some implementations, some of the operations may be performed by or one or more components of a device or a system, such as, a peripheral circuit of the memory device.

At 1102, the memory controller instructs the memory device to write first data (e.g., system data) in a first SLC mode (e.g., the normal SLC mode) using a first program pulse (e.g., the first program pulse 810a of FIG. 8A, or the first program pulse 810b of FIG. 8B).

In some implementations, the memory device writes the first data in the first SLC mode by applying the first program pulse to one or more selected word lines to program memory cells from an erased state to a programmed state (e.g., the programmed state 830a of FIG. 8A, or the programmed state 830b of FIG. 8B).

At 1304, in response to detecting that the memory system is disconnected from an external power source, the memory controller instructs the memory device to write second data (e.g., data associated with unfinished program operations) in a second SLC mode (e.g., the power-loss SLC mode) using a second program pulse (e.g., the second program pulse 820a of FIG. 8A, or the second program pulse 820b of FIG. 8B). The second program pulse is different from the first program pulse. For example, the second program pulse can have a lower voltage, and/or a shorter duration than the first program pulse.

In some implementations, a front interface (e.g., an interface that is coupled to the host) of the memory controller, or a power management circuit of the memory system, can detect a power loss (e.g., whether the memory system is disconnected from the external power source). In response to detecting a power loss, the memory device can be configured to operate in a power loss mode. For example, a power loss protection circuit (e.g., PLP circuit 604 of FIG. 6) can be switched on to provide power for the memory system to complete unfinished operations. The power loss protection circuit can be included in the power management circuit, or can be a discrete circuit from the power management circuit.

In some implementations, in response to detecting a power loss, a back interface (e.g., an interface that is coupled to the memory device) of the memory controller can send a command comprising configuration information (e.g., a set feature) to the memory device. The command comprising configuration information indicates to set a feature of the memory device, so that when the memory device receives a write command to write data in an SLC mode, the memory device can write the data in the second SLC mode. For example, the configuration information can indicate to change a status of a register (e.g., register 515 of FIG. 5) of the memory device, so that the changed status of the register indicates the second SLC mode. If the memory device does not receive the configuration information, when the memory device receives a write command to write data in an SLC mode, the memory device can, by default, write the data in the first SLC mode.

In some implementations, in response to detecting a power loss, the back interface can send a second write command that indicates to write data in the second SLC mode, where the second write command is different (e.g., having extra or different bits) from a write command that indicates to write data in the first SLC mode. In response to receiving the second write command, the memory device can write the data in the second SLC mode.

In some implementations, the memory device writes the second data in the second SLC mode by applying the second program pulse to one or more selected word lines to program memory cells from an erased state to a programmed state (e.g., the programmed state 840a of FIG. 8A, or the programmed state 840b of FIG. 8B).

In some implementations, the memory device comprises memory cells programmable in the first SLC mode, the second SLC mode, and a third storage mode (e.g., an MLC mode, a TLC mode, a QLC mode, or a PLC mode). Memory cells programmable in the third storage mode have a higher storage density than memory cells programmable in the first SLC mode and the second SLC mode. When the memory system is properly powered, the memory system can write user data to the memory device in the third storage mode, for example, by performing two-step program operations as shown in FIGS. 7A-7C.

FIG. 12 illustrates a memory block diagram of an example system 1200 having a memory device, according to some aspects of the present disclosure. System 1200 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. System 1200 can include a host 1208 and a memory system 1202 having one or more memory devices 1204 and a memory controller 1206. Host 1208 can be a processor of an electronic device, such as a central processing unit (CPU), or a system-on-chip (SoC), such as an application processor (AP). Host 1208 can be configured to send or receive data to or from memory devices 1204.

Memory device 1204 can be any memory device disclosed in the present disclosure. Memory controller 1206 is coupled to memory device 1204 and host 1208 and is configured to control the memory device 1204, according to some implementations. Memory controller 1206 can manage the data stored in memory device 1204 and communicate with host 1208. In some implementations, memory controller 1206 is designed for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 1206 is designed for operating in a high duty-cycle environment SSDs or embedded multi-media-cards (eMMCs) used as data storage for mobile devices, such as smartphones, tablets, laptop computers, etc., and enterprise storage arrays. Memory controller 1206 can be configured to control operations of memory device 1204, such as read, erase, and program operations. Memory controller 1206 can also be configured to manage various functions with respect to the data stored or to be stored in memory device 1204 including, but not limited to bad-memory block management, garbage collection, logical-to-physical address conversion, wear leveling, etc. In some implementations, memory controller 1206 is further configured to process error correction codes (ECCs) with respect to the data read from or written to memory device 1204. Any other suitable functions may be performed by memory controller 1206 as well, for example, formatting memory device 1204.

Memory controller 1206 can communicate with an external device (e.g., host 1208) according to a particular communication protocol. For example, memory controller 1206 may communicate with the external device through at least one of various interface protocols, such as a USB protocol, an MMC protocol, a peripheral component interconnection (PCI) protocol, a PCI-express (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 1206 and one or more memory devices 1204 can be integrated into various types of storage devices. For example, memory controller 1206 and one or more memory devices 1204 can be packaged in a universal Flash storage (UFS) package or an eMMC package. In one example as shown in FIG. 13A, memory controller 1206 and a single memory device 1204 may be integrated into a memory card 1302. Memory card 1302 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc. Memory card 1302 can further include a memory card connector 1304 coupling memory card 1302 with a host (e.g., host 1208 in FIG. 12). In another example as shown in FIG. 13B, memory controller 1206 and multiple memory devices 1204 may be integrated into an SSD 1306. SSD 1306 can further include an SSD connector 1308 coupling SSD 1306 with a host (e.g., host 1208 in FIG. 12). In some implementations, the storage capacity and/or the operation speed of SSD 1306 is greater than those of memory card 1302.

The present disclosure also provides a non-transitory computer-readable storage medium. The non-transitory computer-readable storage medium stores one or more instructions (e.g., firmware code of a memory system) that are executable by a processor of a memory controller and/or a peripheral circuit of a memory device. When being executed by the processor of the memory controller and/or the peripheral circuit of the memory device, the instructions in the storage medium can implement method for managing read operations in a memory system in the event of a power loss, as shown in FIGS. 1-7C.

The non-transitory computer-readable storage medium can be an internal storage unit of the device described in any of the foregoing embodiments. For example, the non-transitory computer-readable storage medium can be a hard disk or an internal memory of the device. The non-transitory computer-readable storage medium can also be an external storage device of the device, such as a plug-in hard disk, a smart media card (SMC), a secure digital (SD) card, a flash card, etc. Further, the non-transitory computer-readable storage medium can also include an internal storage unit and an external storage device. In some implementations, the firmware code of the memory system can be stored in a storage medium (e.g., a DRAM coupled to the memory controller) of the memory controller, or in a memory array (e.g., a NAND memory array) of the memory device.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

As used in this disclosure, the terms “a,” “an,” or “the” are used to include one or more than one unless the context clearly dictates otherwise. The term “or” is used to refer to a nonexclusive “or” unless otherwise indicated. The statement “at least one of A and B” has the same meaning as “A, B, or A and B.” In addition, the phraseology or terminology employed in this disclosure, and not otherwise defined, is for the purpose of description only and not of limitation. Any use of section headings is intended to aid reading of the document and is not to be interpreted as limiting; information that is relevant to a section heading may occur within or outside of that particular section.

As used in this disclosure, the term “about” or “approximately” can allow for a degree of variability in a value or range, for example, within 10%, within 5%, or within 1% of a stated value or of a stated limit of a range.

As used in this disclosure, the term “substantially” refers to a majority of, or mostly, as in at least about 50%, 60%, 70%, 80%, 90%, 95%, 96%, 97%, 98%, 99%, 99.5%, 99.9%, 99.99%, or at least about 99.999% or more.

Values expressed in a range format should be interpreted in a flexible manner to include not only the numerical values explicitly recited as the limits of the range, but also to include all the individual numerical values or sub-ranges encompassed within that range as if each numerical value and sub-range is explicitly recited. For example, a range of “0.1% to about 5%” or “0.1% to 5%” should be interpreted to include about 0.1% to about 5%, as well as the individual values (for example, 1%, 2%, 3%, and 4%) and the sub-ranges (for example, 0.1% to 0.5%, 1.1% to 2.2%, 3.3% to 4.4%) within the indicated range. The statement “X to Y” has the same meaning as “about X to about Y,” unless indicated otherwise. Likewise, the statement “X, Y, or Z” has the same meaning as “about X, about Y, or about Z,” unless indicated otherwise.

Particular implementations of the subject matter have been described. Other implementations, alterations, and permutations of the described implementations are within the scope of the following claims as will be apparent to those skilled in the art. While operations are depicted in the drawings or claims in a particular order, such operations are not required be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations are not required in all implementations, and the described components and systems can generally be integrated together or packaged into multiple products.

Accordingly, the previously described example implementations do not define or constrain the present disclosure. Other changes, substitutions, and alterations are also possible without departing from the spirit and scope of the present disclosure.

What is claimed is:

1. A memory system, comprising:
a memory device; and
a memory controller coupled to the memory device, wherein the memory controller is configured to:
instruct the memory device to write first data in a first single-level cell (SLC) mode using a first program pulse; and
in response to detecting that the memory system is disconnected from an external power source, instruct the memory device to write second data in a second SLC mode using a second program pulse, wherein the second program pulse is different from the first program pulse.

2. The memory system of claim 1, wherein the memory device is configured to:
write the first data in the first SLC mode by applying the first program pulse; and
write the second data in the second SLC mode by applying the second program pulse, wherein a voltage of the second program pulse is lower than a voltage of the first program pulse.

3. The memory system of claim 1, wherein the memory device is configured to:
write the first data in the first SLC mode by applying the first program pulse; and
write the second data in the second SLC mode by applying the second program pulse, wherein a duration of the second program pulse is shorter than a duration of the first program pulse.

4. The memory system of claim 1, wherein the memory controller is configured to instruct the memory device to write the second data in the second SLC mode by:
sending configuration information that indicates the second SLC mode; and
sending a write command that instructs the memory device to write the second data.

5. The memory system of claim 1, comprising a power loss protection (PLP) circuit configured to provide power for the memory system when the memory system is disconnected from the external power source.

6. The memory system of claim 5, wherein the PLP circuit comprises a capacitor, wherein the PLP circuit is configured to:
charge the capacitor when the memory system is connected to the external power source; and
discharge the capacitor to provide power for the memory system when the memory system is disconnected from the external power source.

7. The memory system of claim 1, wherein the memory device comprises memory cells programmable in the first SLC mode, the second SLC mode and a third storage mode, wherein memory cells programmable in the third storage mode have a higher storage density than memory cells programmable in the first SLC mode and the second SLC mode.

8. The memory system of claim 7, wherein the third storage mode comprises a triple-level cell (TLC) storage mode or a quad-level cell (QLC) storage mode.

9. A method of operating a memory system, comprising:
writing first data in a first single-level cell (SLC) mode using a first program pulse; and
in response to detecting that the memory system is disconnected from an external power source, writing second data in a second SLC mode using a second program pulse, wherein the second program pulse is different from the first program pulse.

10. The method of claim 9, wherein a voltage of the second program pulse is lower than a voltage of the first program pulse.

11. The method of claim 9, wherein a duration of the second program pulse is shorter than a duration of the first program pulse.

12. The method of claim 9, comprising:
sending configuration information that indicates the second SLC mode; and
sending a write command that instructs a memory device of the memory system to write the second data.

13. The method of claim 9, comprising:
discharging a power loss protection circuit to provide power for the memory system when the memory system is disconnected from the external power source.

14. A memory device, comprising:
a memory array; and
a peripheral circuit coupled to the memory array, wherein the peripheral circuit is configured to:
write first data in a first single-level cell (SLC) mode by applying a first program pulse; and
in response to receiving configuration information that indicates a second SLC mode, write second data in the second SLC mode by applying a second program pulse, wherein the second program pulse is different from the first program pulse.

15. The memory device of claim 14, wherein a voltage of the second program pulse is lower than a voltage of the first program pulse.

16. The memory device of claim 14, wherein a duration of the second program pulse is shorter than a duration of the first program pulse.

17. The memory device of claim 14, wherein the memory device receives the configuration information when an external power source of the memory device is disconnected.

18. The memory device of claim 14, wherein the memory device comprises memory cells programmable in the first SLC mode, the second SLC mode and a third storage mode, wherein memory cells in the third storage mode have a higher storage density than memory cells in the first SLC mode and the second SLC mode.

19. The memory device of claim 18, wherein the third storage mode comprises a triple-level cell (TLC) storage mode or a quad-level cell (QLC) storage mode.

20. The memory device of claim 14, wherein the peripheral circuit is configured to:
apply the second program pulse to a word line to program memory cells coupled to the word line from an erased state to a programmed state.
